(19) United States
(12) Patent Application Publication
(10) Pub. No.: US 2006/0046501 A1
(43) Pub. Date: Mar. 2, 2006

(54) Screening of electroless nickel/immersion gold-plated substrates with black pad defect

(75) Inventor: Sergio Martinez, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/928,937

(22) Filed: Aug. 27, 2004

(51) Int. Cl. H01L 21/302; H01L 21/66

(52) U.S. Cl. 438/754; 438/747; 438/14

(57) ABSTRACT

A method, comprising immersing a package substrate used as part of a semiconductor device in a potassium iodide and iodine solution. The device comprises a substrate, a nickel layer abutting the substrate and comprising a black pad defect, and a gold layer abutting the nickel layer. The method also comprises rinsing the device with deionized water.

### BACKGROUND

Various integrated circuit packages (e.g., ball grid array packages) comprise nickel and gold metallization layers. These metallization layers are used when soldering a package to an application board, such as a printed circuit board (“PCB”). Gold layers are used to protect against oxidation of the nickel surface, and maintain good solderability of the package pad surface to solder balls during a soldering process. The nickel layer is used as an oxidation and diffusion barrier for copper in a substrate pad. One process of plating nickel and gold over a copper pad of a substrate is widely known in the metal plating industry as electroless nickel/immersion gold (“ENIG”). In this process, a nickel layer is plated over the substrate copper pad (base) without the use of an applied electric current, and a gold layer is plated over the nickel by means of immersion of the already nickel-plated substrate into a gold plating bath.

Failure to maintain proper plating bath conditions may result in improperly plated substrates. Among other problems, improper plating causes hypercorrosion of the nickel layer, which can be observed in the form of cracks or dark areas rich in phosphorous content (phosphorous is an inherent component of ENIG plating). For this reason, these dark areas and/or cracks are termed “black pad defects.” During a typical package assembly process, the ENIG-plated substrate is subjected to multiple temperature excursions, which accelerate the rate at which package failure can occur due to black pad. As a result, the package solder joint reliability risk increases significantly compared to average risk of a good ENIG-plated package.

Black pad defects are difficult to detect prior to package assembly because these defects reveal themselves in the nickel layer, which is covered by a thin film of plated gold. For this reason, substrates with this type of defect often go undetected and are incorporated into various electronic devices. Later in device life, black pad defects can cause solder joints (i.e., points on the substrate coupled to solder balls) to become damaged or weakened, possibly rendering the entire device useless.

Current inspection methods used to detect black pad defects use hazardous chemicals such as cyanide-based solutions. Besides the health concerns regarding the handling and use of these substances, sometimes, these chemicals fail to appropriately reveal black pad defects present in the plated nickel layer. Therefore, the use of this type of chemical solutions can be unreliable, a potential to health hazard, and ineffective. As such, there exists no adequate means of detecting black pad defects on ENIG-plated substrates prior to package assembly.

### BRIEF SUMMARY

The problems noted above are solved in large part by a screening process that accurately and reliably reveals black pad defects in ENIG-plated substrates. An exemplary embodiment may be a method comprising immersing a semiconductor device in a potassium iodide and iodine solution. The device comprises a substrate, a nickel layer abutting the substrate and comprising a black pad defect, and a gold layer abutting the nickel layer. The method also comprises rinsing the device with deionized water.

### BRIEF DESCRIPTION OF THE DRAWINGS

For a detailed description of exemplary embodiments of the invention, reference will now be made to the accompanying drawings in which:

FIG. 1 shows a test substrate comprising black pad defects, in accordance with embodiments of the invention; and

FIG. 2 shows a flowchart of a process used to detect black pad defects, in accordance with a preferred embodiment of the invention.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Presented herein is a screening process that accurately and reliably reveals black pad defects in ENIG-plated substrates. Specifically, the process comprises the application of a potassium iodide/iodine etching solution to strip away the gold layer covering the nickel layer, thereby revealing black pad defects present on the nickel layer, and a corrosion inhibitor 1,2,3-benzotriazole (“BTA”) to significantly slow down the etching rate, thereby protecting the revealed nickel surface from unnecessary etching. Because the combination of both the etching solution and the corrosion inhibitor strip away the gold layer while leaving the nickel layer substantially undamaged, this technique detects black pad defects with a relatively high degree of accuracy, compared to techniques currently used in the art.

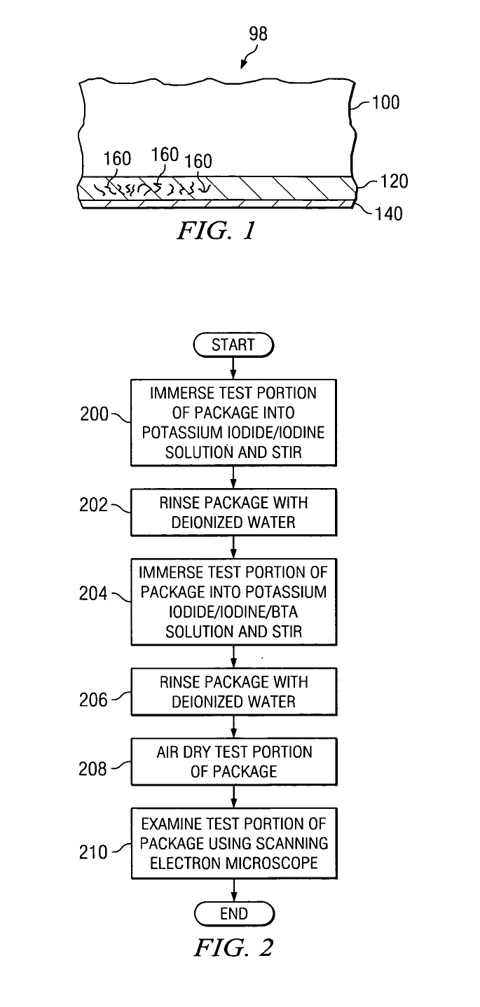

FIG. 1 shows a cross sectional side view of a substrate 100 abutting a nickel layer 120. The nickel layer 120 abuts a gold layer 140. The nickel layer 120 comprises multiple black pad defects 160, although the defects 160 may not be visible prior to performing the defect screening process described below.

FIG. 2 shows the black pad defect screening process mentioned above. The screening process may be used, for example, to detect black pad defects 160 in the substrate 100 as described below. Although not essential, the process preferably is performed at room temperature (e.g., approximately between 293.15 K and 298.15 K). The process may begin by immersing a test portion 98 of the substrate 100 into a potassium iodide and iodine solution and stirring the solution for at least a portion of the duration of the immersion (block 200). The potassium iodide/iodine solution is an oxidizing agent that etches (i.e., strips) away portions of the gold layer 140, thereby at least partially exposing the nickel layer 120. Immersion duration depends on the amount of gold present (i.e., gold layer thickness) and the scope of disclosure is not limited to any specific duration. The potassium iodide concentration preferably is approximately 10 grams/liter and the iodine concentration preferably is approximately 2.5 grams/liter, although the scope of disclosure is not limited to these specific concentrations.

The process may continue by rinsing the test portion 98 of the substrate 100 with water (block 202). Deionized water is preferred, but the scope of disclosure is not limited to deionized water. This rinsing step is preferably performed for approximately between five and ten seconds, although the precise rinsing duration may vary. To reduce the likelihood that the test portion 98 of the substrate 100 (i.e., the portion being etched) receives debris and other particulate matter from the remainder of the substrate 100 (i.e., the portion not being etched), the use of running water is preferred.

The process is further continued by immersing the test portion 98 of the substrate 100 into a potassium iodide/iodine and BTA solution and stirring the solution for at least a portion of the duration of the immersion (block 204). The potassium iodide/iodine solution is an oxidizing agent that etches (i.e., strips) away portions of the gold layer 140 not removed in block 200. The BTA, a corrosion inhibitor, diminishes etching reaction rate once a substantial portion of the gold layer 140 has been etched away. The BTA also protects the nickel layer 120 from the potassium iodide/iodine solution, thus preserving visual evidence of the black pad defects 160. Immersion duration preferably is approximately between ten and fifteen seconds, although the scope of disclosure is not limited to this duration. The potassium iodide concentration preferably is approximately 10 grams/liter, the iodine concentration preferably is approximately 2.5 grams/liter, and the BTA concentration preferably is approximately 5 grams/liter, although the scope of disclosure is not limited to these specific concentrations.

The process is further continued by rinsing the test portion 98 of the substrate 100 with deionized water (block 206). As mentioned above in reference to block 202, the test portion 98 preferably is rinsed using running water. The test portion 98 preferably is rinsed for approximately two minutes, although rinsing duration may vary. Water temperature preferably is approximately at room temperature (e.g., approximately between 293.15 K and 298.15 K); however, the scope of disclosure is not limited to this precise water temperature.

The process is still further continued by air-drying the test portion 98 of the substrate 100 (block 208). Although not essential, the test portion 98 preferably is dried using air blown in a direction facing away from the non-etched portion of the substrate 100, such that debris or other particulate matter is not deposited on the test portion 98.

The final step of the process, shown in block 210, comprises visually examining the test portion 98 for the black pad defects 160 using a scanning electron microscope (“SEM”). The test portion 98 may be scanned for any length of time, although the test portion 98 preferably is scanned for approximately 30 minutes. Because the potassium iodide/iodine solution generally is milder than the cyanide solution used in the art, this process is able to use the potassium iodide/iodine solution to remove the gold layer 140 without damaging the nickel layer 120. Because the nickel layer 120 is substantially undamaged, visual evidence of the black pad defects 160 remains and may be observed using SEM microscopy.

The process described above preferably is applied to a test sample (e.g., three individual substrates) from a substrate lot. If black pad defects are detected in the test samples, then it is possible that a substantial number of substrates in the substrate lot comprise black pad defects. In such a case, the entire lot may be discarded to avoid potential package reliability risks associated with defective substrates. Each sample solution of potassium iodide/iodine and/or potassium iodide/iodine/BTA may be used multiple times before losing chemical strength provided the solution is properly stored and kept away from excessive light exposure.

The above discussion is meant to be illustrative of the principles and various embodiments of the present invention. Numerous variations and modifications will become apparent to those skilled in the art once the above disclosure is fully appreciated. For example, the order of acts depicted in FIG. 2 may be altered from that shown and one or more acts may be eliminated. It is intended that the following claims be interpreted to embrace all such variations and modifications.

What is claimed is:

1. A method, comprising:
immersing a semiconductor device in a potassium iodide and iodine solution, said device comprising a substrate, a nickel layer abutting the substrate and comprising a black pad defect, and a gold layer abutting the nickel layer; and
rinsing the device with deionized water.

2. The method of claim 1, wherein immersing the semiconductor device comprises immersing the semiconductor device in a solution including a potassium iodide concentration of approximately 10 grams/liter, an iodine concentration of approximately 2.5 grams/liter, and a 1,2,3-benzotriazole concentration of approximately 5 grams/liter.

3. The method of claim 2, wherein immersing the semiconductor device comprises immersing the semiconductor device for approximately between ten and fifteen seconds.

4. The method of claim 2, wherein immersing the semiconductor device comprises stirring the solution.

5. The method of claim 1, wherein immersing the semiconductor device comprises removing at least a portion of the gold layer.

6. The method of claim 1, wherein rinsing the semiconductor device comprises rinsing the semiconductor device with deionized water for approximately between five and ten seconds.

7. The method of claim 1, wherein rinsing the semiconductor device comprises rinsing the semiconductor device with deionized water for approximately two minutes.

8. The method of claim 1, further comprising air-drying the semiconductor device for approximately one minute.

9. The method of claim 1, further comprising examining the black pad defect using a scanning electron microscope.

10. The method of claim 1, wherein immersing the semiconductor device comprises immersing the semiconductor device at an ambient temperature of approximately between 293.15 K and 298.15 K.

11. The method of claim 1, wherein immersing the semiconductor device comprises stirring the solution.

12. A method usable in conjunction with a semiconductor package having a substrate, a nickel layer, and a gold layer, comprising:
a step for removing said gold layer and for exposing at least a portion of the nickel layer; and
a step for detecting black pad defects on the nickel layer.

13. The method of claim 12, further comprising a step for rinsing at least a portion of the semiconductor package.

14. The method of claim 12, further comprising a step for drying at least a portion of the semiconductor package.
